(19) United States
(12) Patent Application Publication
(10) Pub. No.: US 2007/0193624 A1
(43) Pub. Date: Aug. 23, 2007

(54) Indium zinc oxide based front contact for photovoltaic device and method of making same

(75) Inventor: Alexey Krasnov, Canton, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/359,775

(22) Filed: Feb. 23, 2006

(51) Int. Cl. H01L 31/00

(52) U.S. Cl. 136/258; 136/261

(57) ABSTRACT

This invention relates to a photovoltaic device including a front contact and/or a method of making the same. In certain example embodiments, the transparent conductive oxide (TCO) front contact is of indium zinc oxide (IZO). In other example embodiments, the IZO may have other element(s) such as silver (Ag) added thereto so that the front contact may be of or include zinc aluminum silver oxide (ZnAlAgO) for example. Moreover, in certain example embodiments the front contact (e.g., IZO or ZnAlAgO) may be sputter-deposited in an oxygen deficient form (substoichiometric); so that subsequent heat treatment or baking used in the photovoltaic device manufacturing (e.g., for subsequent layer formation) results in an optimal stoichiometry which may or may not be substoichiometric in the final product.

This invention relates to a photovoltaic device including a front contact. In certain example embodiments, the transparent conductive oxide (TCO) front contact is of indium zinc oxide (IZO). In other example embodiments, the IZO may have other element(s) such as silver (Ag) added thereto so that the front contact may be of or include zinc aluminum silver oxide (ZnAlAgO) for example. Moreover, in certain example embodiments the front contact (e.g., IZO or ZnAlAgO) may be sputter-deposited in a non-stoichiometric and oxygen deficient form; so that subsequent baking or heat treatment contact with the body of the photovoltaic device causes further optimization of the front contact such that additional oxiding thereof occurs thereby resulting in an optimal stoichiometry which may or may not be substoichiometric in the final product.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603 and 6,123,824, the disclosures of which are hereby incorporated herein by reference). Amorphous silicon photovoltaic devices, for example, include a front contact or electrode. Typically, the front contact is made of a transparent conductive oxide (TCO) formed on a substrate such as a glass substrate. In many instances, the front contact is formed using a method of chemical pyrolysis where precursors are sprayed onto the glass substrate at approximately 400 to 500 degrees C. Unfortunately, front contact TCO films such as SnO₂:F (fluorine doped tin oxide) formed on glass substrates by chemical pyrolysis suffer from non-uniformity and thus may be unpredictable and/or inconsistent with respect to certain optical and/or electrical properties.

Thus, it will be appreciated that there exists a need in the art for an improved front contact material for photovoltaic devices.

It has been found that a TCO of or including indium zinc oxide (IZO) is highly advantageous for front contact applications in photovoltaic devices (e.g., such as amorphous silicon based photovoltaic devices). Advantages of IZO include its ability to be deposited in a conductive manner at approximately room temperature (e.g., via sputtering). Moreover, when deposited at certain indium/zinc ratios and/or using certain conditions, the IZO based front contact has been found to increase its electrically conductivity when baked at temperatures such as 200-400 degrees C., more preferably from about 200-300 degrees C. (similar temperatures may be used in a-Si solar cell manufacturing techniques to improve stack performance).

In certain example embodiments of this invention, the IZO based front contact is deposited in an oxygen deficient (substoichiometric) manner. Sputtering at approximately room temperature may be used for the deposition of the front contact in certain example instances, although other techniques may instead be used in certain instances. For example, the IZO based front contact may be sputter-deposited using a ceramic target(s), or may be sputter-deposited using a metal target of InZn (or ZnAlAg) in a reactive sputtering atmosphere including argon and oxygen gas. The gas composition or mixture may be chosen so as to make the initially deposited material substoichiometric, so that subsequent baking during heat treatment of the photovoltaic device results in an optimal IZO or ZnAlAgO stoichiometry (e.g., an appropriate amount of oxiding) for the TCO front contact.

In certain example embodiments of this invention, the TCO front contact is substantially free, or entirely free, of fluorine. In certain example embodiments of this invention, the TCO front contact may have a sheet resistance (Rₛ) of from about 7-50 more preferably from about 10-25 ohms/square, and most preferably from about 10-15 ohms/square using a reference example non-limiting thickness of from about 1,000 to 2,000 angstroms.

Sputter deposition of a TCO (transparent conductive oxide) at approximately room temperature for a front contact would be desirable, given that most float glass manufacturing platforms are not equipped with in-situ heating systems. Moreover, an additional potential advantage of sputter-deposited TCO films is that they may include the integration of anti-reflection coatings, resistivity reduction, and so forth. For example, a single or multi-layer anti-reflection coating may be provided between the glass substrate and the TCO front contact.

In certain example embodiments of this invention, there is provided an amorphous silicon based photovoltaic device comprising: a front glass substrate; an active semiconductor film comprising amorphous silicon; an electrically conductive and substantially transparent front electrode located between at least the front glass substrate and the active semiconductor film; a back electrode, wherein the active semiconductor film is provided between at least the front electrode and the back electrode; and wherein the front electrode comprises indium zinc oxide. In certain example embodiments, a glass superstrate is also provided, wherein the back electrode is located between at least the glass superstrate and the active semiconductor film. In certain example embodiments, a ratio In/Zn in the front electrode comprising indium zinc oxide is from about 7/1 to 13/1, more preferably from about 8/1 to 10/1.

In certain example embodiments of this invention, there is provided a photovoltaic device comprising: a front glass substrate; an active semiconductor film; an electrically conductive and substantially transparent front electrode located between at least the front glass substrate and the active semiconductor film; and wherein the front electrode comprises IZO and/or ZnAlAgO.

In other example embodiments of this invention, there is provided a method of making a photovoltaic device, the method comprising: sputter-depositing a front electrode comprising indium zinc oxide on a glass substrate at approximately room temperature; forming an active semiconductor film on the glass substrate over at least the front electrode comprising indium zinc oxide; and during or following the forming of the active semiconductor film, subjecting at least the front electrode to heat treatment of at least about 200 degrees C. which further oxides the front electrode comprising indium zinc oxide so as to achieve a desired stoichiometry thereof.

### BRIEF DESCRIPTION OF THE DRAWINGS

FIG. 1 is a cross sectional view of an example photovoltaic device according to an example embodiment of this invention.

FIG. 2 is a flowchart illustrating a method of making a photovoltaic device according to an example embodiment of this invention.

### DETAILED DESCRIPTION OF EXAMPLE EMBODIMENTS OF THE INVENTION

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., one or more amorphous silicon layers) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having an n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon layer (which may include one or more layers such as p, n and i layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances.

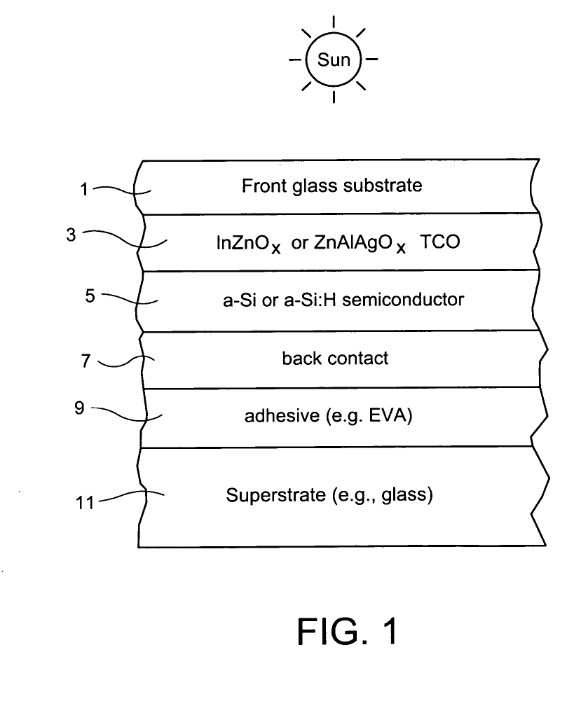

FIG. 1 is a cross sectional view of a photovoltaic device according to an example embodiment of this invention. The photovoltaic device includes transparent front glass substrate 1, front electrode or contact 3 which is of or includes a TCO such as indium zinc oxide (IZO) and/or zinc aluminum silver oxide (ZnAlAgO), active semiconductor film 5 of one or more semiconductor layers, back electrode or contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may be provided in the device, such as between the front glass substrate 1 and the front contact 3, or between other layers of the device.

It has been found that a TCO of or including indium zinc oxide (IZO) is highly advantageous for conductive front electrode or contact 3. Advantages of IZO include its ability to be deposited in a conductive manner at approximately room temperature (e.g., via sputtering). Moreover, when deposited at certain indium/zinc ratios and/or using certain conditions, the IZO based front contact 3 has been found to increase its electrically conductivity when subsequently baked at temperatures such as 200-400 degrees C., more preferably from about 200-300 degrees C. (similar temperatures may be used in a-Si solar cell manufacturing techniques to improve stack performance).

In certain example embodiments of this invention, the TCO front electrode or contact 3 is substantially free, or entirely free, of fluorine. This may be advantageous for pollutant issues. In certain example embodiments of this invention, the TCO front contact 3 before and/or after the heat treatment may have a sheet resistance (Rₛ) of from about 7-50 ohms/square, more preferably from about 10-25 ohms/square, and most preferably from about 10-15 ohms/square using a reference example non-limiting thickness of from about 1,000 to 2,000 angstroms, so as to ensure adequate conductivity.

An additional potential advantage of sputter-deposited TCO films for front electrodes/contacts 3 is that they may permit the integration of an anti-reflection and/or colour-compression coating (not shown) between the front contact 3 and the glass substrate 1. The anti-reflection coating (not shown) may include one or multiple layers in different embodiments of this invention. For example, the anti-reflection coating may include a high refractive index dielectric layer immediately adjacent the glass substrate 1 and another layer of a lower refractive index dielectric immediately adjacent the front contact 3. Thus, since the front contact is on the glass substrate 1, it will be appreciated that the word “on” as used herein covers both directly on and indirectly on with other layers therebetween.

The front electrodes or contacts 3 of or including IZO may be of any suitable stoichiometry in certain embodiments of this invention. However, most preferred is a ratio of In/Zn in the TCO layer 3 of from about 7/1 to 13/1, more preferably from about 8/1 to 10/1. It has been found that such ratios are advantageous with respect to durability and conductivity in electrode applications.

In certain example embodiments of this invention, the IZO (or InZnOx) as deposited for front electrode/contact film 3 is amorphous, and may remain amorphous after annealing. It is noted that IZO is a substitutional type material, meaning that two materials (for instance, In₂O₃ and ZnO) fuse together to produce a new alloy. Typically, when the IZO is amorphous maximum conductivity can be reached. In other words, an amorphous front electrode 3 is advantageous in that improved conductivity can be achieved. However, in other example embodiments of this invention, the IZO need not be amorphous and may be crystalline for example.

Front glass substrate 1 and/or rear superstrate 11 may be made of soda-lime-silica based glass in certain example embodiments of this invention. While substrates 1, 11 may be of glass in certain example embodiments of this invention, other materials such as quartz or the like may instead be used. Moreover, superstrate 11 is optional in certain instances. Glass 1 and/or 11 may or may not be thermally tempered in different embodiments of this invention.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. These amorphous silicon based layers of film 5 may be of hydrogenated amorphous silicon in certain instances, but may also be of or include hydrogenated amorphous silicon carbon or hydrogenated amorphous silicon germanium, or other suitable material(s) in certain example embodiments of this invention. It is possible for the active region 5 to be of a double-junction type in alternative embodiments of this invention.

Back contact or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact.

The photovoltaic module may be encapsulated or partially covered with an encapsulating material such as encapsulant 9 in certain example embodiments. An example encapsulant or adhesive for layer 9 is EVA. However, other materials such as Tedlar type plastic, Nuvasil type plastic, Tefzel type plastic or the like may instead be used for layer 9 in different instances.

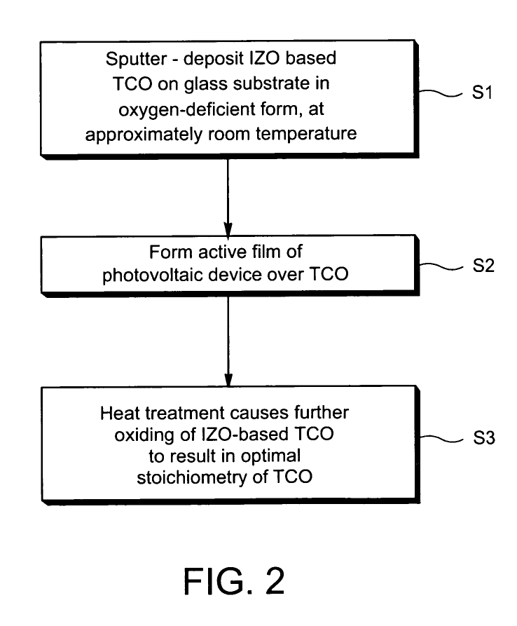

FIG. 2 is a flowchart illustrating steps in making a photovoltaic device according to certain example embodiments of this invention. In this example embodiment, the IZO based front contact 3 is deposited in an oxygen deficient (substoichiometric) manner. Sputtering at approximately room temperature may be used for the deposition of the front contact in certain example instances, although other techniques may instead be used in certain instances. In S1 of FIG. 2, the IZO based front contact 3 may be sputter-deposited at approximately room temperature on (directly or indirectly) glass substrate 1 using a ceramic target(s), or may be sputter-deposited using a metal target of InZn (or ZnAlAg) in a reactive sputtering atmosphere including argon and oxygen gas. The gas composition or mixture may be chosen in S1 so as to make the initially deposited material substoichiometric or oxygen deficient. Thereafter, in S2 other layers of the device such as film 5 (and optionally layers 7 and/or 9) are formed over the front contact. In S3, heat treatment such as baking used during manufacturing of the photovoltaic device causes the optimal stoichiometry (e.g., by oxiding or the like) of the front contact 3 and thus an optimal IZO or ZnAlAgO stoichiometry for the TCO front contact results following the heat treatment. The heat treatment of S3 may be performed during or after formation of one or more of layers 5, 7 and/or 9 of the device. Moreover, the heat treatment may use temperatures of from about 200-400, more preferably from about 200-300 degrees C.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. An amorphous silicon based photovoltaic device comprising:
a front glass substrate;
an active semiconductor film comprising amorphous silicon;
an electrically conductive and substantially transparent front electrode located between at least the front glass substrate and the active semiconductor film;
a back electrode, wherein the active semiconductor film is provided between at least the front electrode and the back electrode; and
wherein the front electrode comprises indium zinc oxide.

2. The photovoltaic device of claim 1, further comprising a glass superstrate, wherein the back electrode is located between at least the glass superstrate and the active semiconductor film.

3. The photovoltaic device of claim 1, wherein a ratio In/Zn in the front electrode comprising indium zinc oxide is from about 7/1 to 13/1.

4. The photovoltaic device of claim 1, wherein a ratio In/Zn in the front electrode comprising indium zinc oxide is from about 8/1 to 10/1.

5. The photovoltaic device of claim 1, wherein the front electrode comprises amorphous indium zinc oxide.

6. The photovoltaic device of claim 2, further comprising a layer comprising EVA located between the glass superstrate and the back electrode.

7. The photovoltaic device of claim 1, wherein the back electrode comprises indium zinc oxide.

8. The photovoltaic device of claim 1, wherein the front electrode has a sheet resistance (Rₛ) of from about 7-50 ohms/square.

9. The photovoltaic device of claim 1, wherein the front electrode has a sheet resistance (Rₛ) of from about 10-15 ohms/square.

10. The photovoltaic device of claim 1, wherein the amorphous silicon is hydrogenated.

11. A photovoltaic device comprising:
a front glass substrate;
an active semiconductor film;
an electrically conductive and substantially transparent front electrode located between at least the front glass substrate and the active semiconductor film; and
wherein the front electrode comprises IZO and/or ZnAlAgO.

12. The photovoltaic device of claim 11, further comprising a glass superstrate, and wherein the back electrode is located between at least the glass superstrate and the active semiconductor film.

13. The photovoltaic device of claim 11, wherein the front electrode comprises IZO, and wherein a ratio In/Zn in the front electrode comprising IZO is from about 7/1 to 13/1.

14. The photovoltaic device of claim 13, wherein the ratio In/Zn is from about 8/1 to 10/1.

15. The photovoltaic device of claim 11, wherein the front electrode is amorphous.

16. The photovoltaic device of claim 11, wherein the front electrode has a sheet resistance (Rₛ) of from about 10-20 ohms/square.

17. A method of making a photovoltaic device, the method comprising:
sputter-depositing a front electrode comprising indium zinc oxide on a glass substrate at approximately room temperature;
forming an active semiconductor film on the glass substrate over at least the front electrode comprising indium zinc oxide; and
during or following the forming of the active semiconductor film, subjecting at least the front electrode to heat treatment of at least about 200 degrees C. which further oxides the front electrode comprising indium zinc oxide so as to achieve a desired stoichiometry thereof.

18. The method of claim 17, wherein the heat treating is from about 200-400 degrees C.

19. The method of claim 17, wherein the front electrode is amorphous before and after the heat treating.

20. The method of claim 17, wherein a ratio In/Zn in the front electrode is from about 7/1 to 13/1.
